(19) United States
(12) Patent Application Publication
(10) Pub. No.: US 2018/0155567 A1
(43) Pub. Date: Jun. 7, 2018

(54) INK COMPOSITION FOR PRINTING, AND PRINTING METHOD USING SAME

(71) Applicant: LG CHEM, LTD., Seoul (KR)

(72) Inventors: Jiehyun SEONG, Daejeon (KR); Joo Yeon KIM, Daejeon (KR); Young Chang Byun, Daejeon (KR); Jung Hyun SEO, Daejeon (KR); Seung Heon LEE, Daejeon (KR); Ji Young HWANG, Daejeon (KR); Yong Goo SON, Daejeon (KR); Beom Mo KOO, Daejeon (KR)

(73) Assignee: LG CHEM, LTD., Seoul (KR)

(21) Appl. No.: 15/886,165

(22) Filed: Feb. 1, 2018

Related U.S. Application Data
(63) Continuation of application No. 13/982,721, filed on Jul. 30, 2013, now abandoned.

(30) Foreign Application Priority Data
Feb. 8, 2011 (KR) 10-2011-0011185

(51) Int. Cl. C09D 11/52; C09D 11/037; C09D 11/033; H05K 3/12; H05K 1/09

(52) U.S. Cl. CPC C09D 11/52; C09D 11/037; H05K 1/097; H05K 3/1275; C09D 11/033

(57) ABSTRACT

Provided are an ink composition for a printing method, in which the ink composition is applied to a printing blanket, a portion of a coating film is removed using a cliche, and then the coating film remaining on the printing blanket is transferred to an object to be printed, in which the ink composition before printing satisfies the following [Equation 1] [INK_{ST}≤BNKγc] and the ink coating film on the printing blanket satisfies the following [Equation 2] [BNKγc≤INK_{SE}≤SUB_{SE}] immediately before the removal of the portion of the ink coating film from the printing blanket using the cliche, and a printing method using the same.

### CROSS-REFERENCE TO RELATED APPLICATIONS

This application is a continuation of U.S. application Ser. No. 13/982,721, filed Jul. 30, 2013, which is a national stage entry of International Application No. PCT/KR2012/000936, filed on Feb. 8, 2012, which claims priority to and the benefit of Korean Patent Application No. 10-2011-0011185 filed in the Korean Intellectual Property Office on Feb. 8, 2011, the entire contents of which are incorporated herein by reference.

### TECHNICAL FIELD

The present invention relates to an ink composition for printing and a printing method using the same. More particularly, the present invention relates to an ink composition for printing a fine pattern for forming the fine pattern and a printing method using the same.

### BACKGROUND ART

In electronic devices such as touch screens, displays, semiconductors and the like, a pattern used in various parts is required. For example, in most of the electronic devices, conductive parts such as electrodes are used. As the high performance of the aforementioned electronic device proceeds, finer patterns are required in the parts of the electronic device.

Methods for forming a pattern in the related art are diversified according to the use thereof, and representative examples thereof include a photolithography method, a screen printing method, an inkjet method, and the like.

For example, the photolithography method is a method of forming an etching protective layer on a layer which requires patterning, for example, a glass or film, on which metal is deposited, selectively exposing and developing the layer to be patterned, selectively etching the metal by using the patterned etching protective layer, and then peeling off the etching protective layer.

However, the photolithography method uses an etching protective layer material and a stripping solution, which are not the constituting elements of the pattern itself, thereby causing an increase in process costs due to costs of the etching protective layer material and the stripping solution and disposal costs thereof. Further, there is a problem of environmental pollution caused by disposal of the materials. In addition, the method has many processes and is complicated, and thus needs a lot of time and costs, and when the etching protective layer material is not sufficiently peeled off, there are problems in that defects are generated in a final product and the like.

The screen printing method is carried out by using an ink which is based on particles having a size from several hundred nanometers to several tens of micrometers for screen printing and then performing sintering.

The screen printing method and the inkjet method have limitations in implementing a fine pattern having a size of several tens of micrometers.

### SUMMARY OF THE INVENTION

The present invention has been made in an effort to provide an ink composition that is suitable for a reverse offset printing method and a printing method using the same by finding that the composition of the ink composition is changed as time passes and physical properties need to be controlled in the relationship between constituting elements mutually related in the printing process.

An exemplary embodiment of the present invention provides an ink composition for a printing method, in which the ink composition is applied to a printing blanket, a portion of a coating film is removed using a cliche, and then the coating film remaining on the printing blanket is transferred to an object to be printed, in which the ink composition before printing satisfies the following [Equation 1] and the ink printing film on the printing blanket satisfies the following [Equation 2] immediately before the removal of the portion of the ink coating film from the printing blanket using the cliche.

INK_{ST}≤BNKγc [Equation 1]

BNKγc≤INK_{SE}≤SUB_{SE} [Equation 2]

In Equations 1 and 2,

INK_{ST} is an initial surface tension of the ink composition,

BNKγc is a critical surface tension of wetting of the printing blanket,

INK_{SE} is a surface energy of the ink coating film on the printing blanket, and

SUB_{SE} is a surface energy of the object to be printed.

Another exemplary embodiment of the present invention provides a printing method using the ink composition. The printing method includes applying the ink composition on a printing blanket, removing a portion of a coating film on the printing blanket using a cliche, and transferring the coating film remaining on the printing blanket to an object to be printed.

The ink composition according to the present invention is prepared such that the change in physical properties over time satisfies Equations 1 and 2 as described above, and thus is appropriate for a reverse offset printing method. Furthermore, a fine pattern may be implemented by using the ink composition according to the present invention.

### BRIEF DESCRIPTION OF THE DRAWINGS

FIG. 1 is a process schematic view of a reverse offset printing method.

FIG. 2 is a photo illustrating a fine pattern prepared in Example 1.

### DETAILED DESCRIPTION

Hereinafter, the present invention will be described in more detail.

The present invention relates to an ink composition for a printing method, in which the ink composition is applied to a printing blanket, a portion of a coating film is removed using a cliche, and then the coating film remaining on the printing blanket is transferred to an object to be printed, in which the ink composition before printing satisfies the following [Equation 1] and the ink printing film on the printing blanket satisfies the following [Equation 2] immediately before the removal of the portion of the ink coating film from the printing blanket using the cliche.

INK_{ST}≤BNKγc [Equation 1]

BNKγc≤INK_{SE}≤SUB_{SE} [Equation 2]

In Equations 1 and 2,

INK_{ST} is an initial surface tension of the ink composition,

BNKγc is a critical surface tension of wetting of the printing blanket,

INK_{SE} is a surface energy of the ink coating film on the printing blanket, and

SUB_{SE} is a surface energy of the object to be printed.

In the present invention, the ink composition preferably includes a particle and a solvent. The ink composition may additionally include binder, and may further include a surfactant.

The particle may be any kind of particle, but it is preferred that a functional particle imparting characteristics that are suitable for the use of ink, for example, a conductive particle, a magnetic particle, insulating particle or the like is used from the viewpoint of being suitable for the use of ink. The range of the particle diameter is not particularly limited, but is preferably from 5 nm to 800 nm. When the particle diameter of the particle exceeds 800 nm, it is lmited in implementing a fine line width less than 10 micrometers, and when the particle diameter of the particle is less than 5 nm, it is difficult to prepare the particle and to be stably present in the ink without particle aggregation.

When the use of the ink is to implement a conductive pattern on an object to be printed, a conductive particle may be used as the particle. It is preferred that a silver particle is used as the conductive particle, but without being limited thereto, it is possible to use a copper particle, a palladium particle, a gold particle, a nickel particle, a conductive polymer particle, a mixture thereof or the like.

The content of the particle is not particularly limited, but it is preferred that the particle is included in the ink composition in a range from 10 parts by weight to 50 parts by weight based on 100 parts by weight of the entire ink. When the content of the particle exceeds 50 parts by weight, the range of selection that may control other components in the ink is narrowed in order to satisfy Equations 1 and 2. When the content of the particle is less than 10 parts by weight, functional components, which implement the functionality of the ink, for example, conductivity, are unnecessarily decreased, which is not efficient.

When the ink composition includes a binder, it is preferred that the surface tension of the binder is from 26 mN/m to 45 mN/m to satisfy the Equations as described above. The reason is as follows. In the fine pattern printing, the surface energy of glass, metal, a polyethylene terephthalate (PET) film and the like, which are a general object to be printed, is from 40 mN/m to 70 mN/m. The appropriate range of the INK_{SE}, which is the surface energy of the ink coating film on the printing blanket, becomes different depending on the object to be printed. However, when the surface tension of the binder is typically from 26 mN/m to 45 mN/m, it is easy for the object to be printed having an SUB_{SE} (the surface energy of the object to be printed) value from 40 mN/m to 70 mN/m to satisfy Equation 2 by appropriately controlling the content of the binder in the ink composition or the selection of a particle and a liquid that is the solvent.

Even when the surface tension of the binder is out of the range, it is also possible to appropriately control the content of the binder in the ink composition or the selection of a particle and a liquid that is the solvent so as to satisfy Equation 2, but the selectable range becomes much more narrow than the case in which a binder having a surface tension within the above-described range is used.

Examples of a binder having the physical properties include a novolac resin, a butyl acrylic resin, a butyl methacrylic resin, a benzyl methacrylic resin, an ethyl methacrylic resin, a methyl methacrylate-based resin, polyvinylpyrrolidone, ethyl cellulose, hydroxypropylmethyl cellulose, styrene resin, a polyvinyl acetate-based resin, a copolymer of at least two thereof and the like.

The binder preferably included in the ink composition in a range preferably from 0.1 part by weight to 20 parts by weight based on 100 parts by weight of the entire ink composition. When the content of the binder is less than 0.1 part by weight it is not easy to form a good-quality ink coating film having no defects such as cracks, pin holes and the like on a blanket and on an object to be printed after being transferred. When the content of the binder exceeds 20 parts by weight, functional components, which implement the functionality of the ink, are unnecessarily decreased, which is not efficient.

It is preferred that the ink composition includes a liquid having a surface tension from 26 mN/m to 72 mN/m in an amount of 0. 1% by weight or more. It is preferred that the liquid having the surface tension as described above has low volatility, and example, the vapor pressure is preferably 3 Torr or less at 25° C. It is possible to control the content of the liquid as described above such that the ink composition satisfies Equations 1 and 2, particularly, Equation 2. The reason is as follows. The INK_{SE} in Equation 2 a surface energy of an ink coating film formed by appropriately drying the ink coated on the printing blanket. Since high volatile components have been already volatilized when the ink coated on the printing blanket is appropriately dried, the main components of the ink coating film remaining on the surface of the blanket are the particle, the binder and the low-volatile liquid component, and thus the INK_{SE} is determined by the surface tensions thereof. Meanwhile, in the fine pattern printing, the surface energy SUB_{SE} of glass, metal, a polyethylene terephthalate (PET) film and the like, which are a general object to be printed, is from 40 mN/m to 70 mN/m. Accordingly, when the surface tension of the low-volatile liquid is from 26 mN/m to 72 mN/m, it is easy to satisfy Equation 2 by appropriately controlling the content of the low-volatile liquid or the selection of the binder or the particle.

In the related art, an attempt to improve the physical properties of an ink composition, a printing process using the same or a product prepared therefrom has been made by controlling the absolute values of physical properties of an ink composition at a specific time point. However, the composition of the ink composition applied to a printing method inevitably changes as time passes, and different process times are required step by step in the printing process. Based on the fact, the present inventors have found that it is important to control the physical properties of the ink composition each required in each step of the printing process, that is, at different time points, rather than those at one time point.

Specifically, the ink composition needs to be applied well on a printing blanket in the initial stage at a time point of being applied on the printing blanket. That is, it is preferred that the ink composition is appropriately spread on the surface of the printing blanket and the printing blanket is appropriately swollen.

However, in the removing of a portion of an ink coating film applied on the printing blanket using a cliche, the ink coating film in a portion, which is in contact with the cliche, needs to be separated well from the printing blanket, whereas the ink coating film, which is not in contact with the cliche, remains on the printing blanket. Further, the ink coating film in a portion, which is in contact with the cliche, needs to be attached to the cliche well.

In addition, when the ink coating film remaining on the printing blanket is subsequently brought into contact with an object to be printed, all of the ink coating film needs to be separated from the printing blanket and transferred to the object to be printed.

In other words, the ink composition requires different adhesion and cohesion for different objects in each step of the printing process.

Thus, in the present invention, Equations 1 and 2 have been deduced as conditions for allowing the ink composition to optimally have physical properties required in the printing process as described above at two time points, that is, before printing and before removing a portion of the ink coating film from the printing blanket. It is possible to provide an ink composition suitable for the printing method by controlling the ink composition such that the ink composition satisfies each of Equations 1 and 2at different time points, and accordingly, it is also possible to provide a fine pattern.

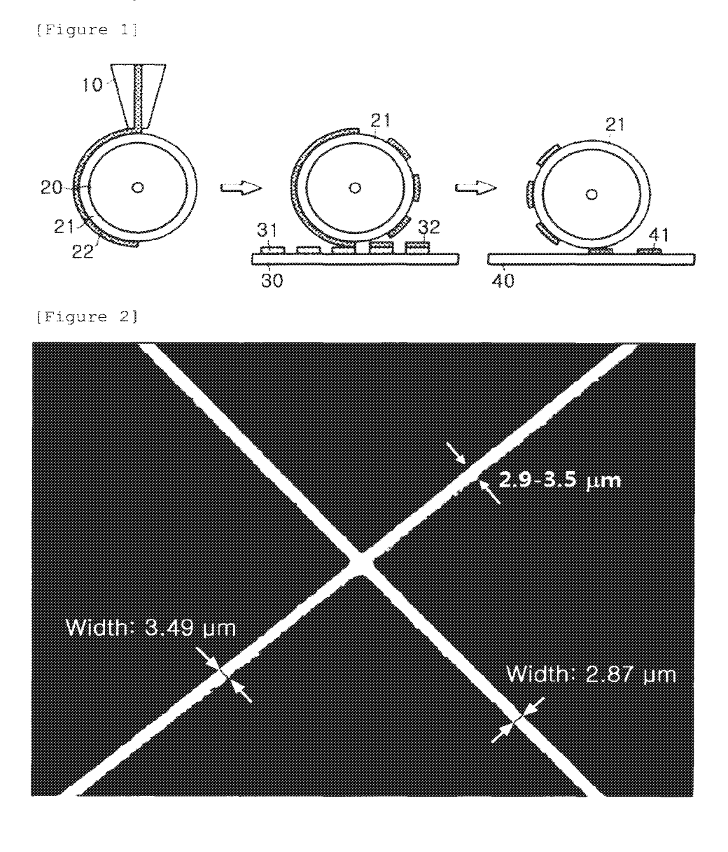

Specifically, the schematic view of the printing method is illustrated in FIG. 1. The printing method includes: i) applying the ink composition on a printing blanket; ii) bringing a cliche with a pattern thereof formed as an engraved shape into contact with the printing blanket to form a pattern of the ink composition, which corresponds to the pattern, on the printing blanket; and iii) transferring the pattern of the ink composition on the printing blanket to an object to be printed.

FIG. 1, reference numeral 10 is a coater for coating the ink composition, reference numeral 20 is a roll-type support, reference numeral 21 is a blanket for surrounding the roll-type support, and reference numeral 22 is an ink composition applied on the blanket. Reference numeral 30 is a cliche support and reference numeral 31 is a cliche having a pattern, in which a pattern corresponding to a pattern to be formed is formed in an engraved shape. Reference numeral 40 is an object to be printed and reference numeral 41 is a pattern of the ink composition which is transferred to an object to be printed.

The initial surface tension of the ink composition needs to be a critical surface tension of wetting of the printing blanket (BNKγc) surface or less so as to uniformly coat the ink composition in step i) of FIG. 1 without being dewetted on the surface of the printing blanket.

The initial surface tension of the ink composition may be controlled with a surfactant and/or a solvent. As the surfactant, it is possible to use a typical leveling agent, for example, a silicone-based, fluorine-based or polyether-based surfactant, and the content thereof is preferably within 0.01% by weight to 5% by weight.

The selection of a solvent is not particularly limited as long as the surface tension of the entire ink composition satisfies the condition of Equation 1, but it is preferred that two or more solvents having different volatilities are used together. For example, it is possible to use a first solvent showing high volatility exceeding a vapor pressure of 3 Torr at 25° C. and a second solvent showing relatively low volatility of a vapor pressure of 3 Torr or less at 25° C. In this case, the second solvent acts as a dispersion medium of the ink composition before printing, and before the heat treatment, if necessary. The first solvent may maintain low viscosity of an ink composition and excellent coatability thereof for a roller together with the second solvent until the ink composition applied on a base material or the roller, and may be removed by volatilization to increase the viscosity of the ink composition and form and maintain a pattern on the roller well.

In the above-described case, it is preferred to use a solvent having a low surface tension that is the critical surface tension of wetting (γc) or less on the surface of the printing blanket, as the surface tension of at least one or more solvents. When silicone rubber is used as a material for the surface of the printing blanket, γc of the silicone rubber is about 24 mN/m (Jones R G, Ando W and Chojnowsk J 2000 Silicon-Containing Polymers (New York: Kluwer) p 214), and thus is preferred that the surface tension of at least one or more solvents in the ink is specifically from 11 mN/m to 24 mN/m.

This is for preventing the dewetting and pin holes from being generated when the ink composition is coated on the surface of the printing blanket and for smoothly coating the ink composition thereon.

As described above, when two or more solvents having different volatilities are used together, the solvent having the low surface tension is preferably the first solvent having high volatility, and specifically, the vapor pressure thereof is preferably 3 Torr or more at 25° C. When silicone rubber is used as the material for the surface of the printing blanket, the γc of silicone rubber is about 24 mN/m, and thus examples of a solvent that corresponds to the value include dimethyl glycol, trimethyl chloro methane, methanol, ethanol, isopropanol, propanol, hexane, heptane, octane, 1-chlorobutane, methyl ethyl ketone, cyclohexane and the like.

When two or more solvents having different volatilities are used together, it is preferred that the second solvent having low viscosity specifically has a vapor pressure of 3 Torr or less at 25° C. It is preferred that the surface tension of the low volatile solvent is higher than that of the high volatile solvent. As described above, the ink composition according to the present invention may include a liquid having a surface tension from 26 mN/m to 72 mN/m and a vapor pressure of 3 Torr or less at 25° C. in an amount of 0.1% by weight or more, and when two or more solvents having different volatilities are used together, it is possible to replace the liquid with the second solvent having low volatility, or to simultaneously use the second solvent and the liquid. Examples of the low volatile solvent having a vapor pressure of 3 Torr or less at 25° C. include dimethyl acetamide, γ-butyl lactone, hydroxytoluene, propylene glycol monobutyl ether, propylene glycol monopropyl ether, butyl cellosolve, glycerin, butyl carbitol, methoxy propoxy propanol, carbitol, terpinol, triethylene glycol monoethyl ether, triethylene glycol monomethyl ether, N-methylpyrrolidone, propylene carbonate, dimethyl sulfoxide, diethylene glycol, triethanolamine, diethanolamine, triethylene glycol, ethylene glycol and the like.

The rate of forming an ink coating film on a printing blanket by coating an ink composition on the printing blanket and then volatilizing volatile components in the ink composition has a close relationship with an amount of high volatile solvent and low volatile solvent used. Accordingly, the amount of high volatile solvent and low volatile solvent used may be determined by considering the use thereof, the working environment and the like. In order to shorten the tact time of the entire process by rapidly forming the ink coating film, it is preferred that the amount of high volatile solvent used is decreased, and in order to secure a time to spare in the process by delaying the rate of forming the ink coating film, it is preferred that the amount of high volatile solvent used is increased. Preferably, it is possible to control the low volatile solvent in a range from 10% by weight to 40% by weight and high volatile solvent in a range from 0.1% by weight to 50% by weight.

In step ii) of FIG. 1, when an ink coating film coated on a printing blanket contacts a cliche, a pattern of the ink composition, which corresponds to the pattern, is formed on the printing blanket by transferring the ink coating film on a portion in contact with each other to the cliche side to be removed, and subsequently, in step iii), the pattern of the ink composition on the printing blanket is transferred to an object to be printed. In order to smoothly conduct the procedure, it is preferred that Equation 2 is satisfied.

At this time, the surface energy of the ink coating film on the printing blanket and the surface energy of the object to be printed may be obtained by a method devised by Fowkes (Fowkes, F. M. Ind. Eng. Chem. 1964, 56, 40; Owens, D. K.; Wendt, R. C. J. Appl. Polym. Sci. 1969, 13, 1741). The procedure will be explained as follows.

Among the γ_{S} that is the surface energy of the solid surface, the γ_{L} that is the surface tension of the liquid, and the θ that is the contact angle of the liquid on the solid, the following relationship is established.

γ_{L}(1+cos θ)=2(\sqrt{γ_{L}^{P}γ_{S}^{p}}+\sqrt{γ_{L}^{d}γ_{S}^{d}}) [Equation 3]

At this time, γ_{L}^{P} and γ_{S}^{P} represent polar portions of the surface energy of liquid and solid, respectively, and γ_{L}^{d} and γ_{S}^{d} represent dispersive portions of the surface energy of liquid and solid, respectively. Moreover, the surface energy γ of a material is represented as the sum of γ_{d} that is a dispersive portion and γ_{P} that is a polar portion.

The equation may be rearranged as follows.

$$\frac{{γ}_{L} ( 1 + cos θ )}{2 \sqrt{{γ}_{L}^{d}}} = \sqrt{{γ}_{S}^{p} ( \frac{{γ}_{L}^{p}}{{γ}_{L}^{d}} )} + \sqrt{{γ}_{S}^{d}} \qquad [ Equation 4 ]$$

Accordingly, when γ_{L}, γ_{L}^{P} and γ_{L}^{d} which are information on the surface tension of liquid are known, γ_{S}^{p} and Y_{S}^{d}, which are information on the surface energy of solid, may be obtained by measuring the contact angle θ of the liquid on the solid, and the total surface energy of the solid may also be obtained from the sum of γ_{S}^{p} and γ_{S}^{d} thereupon.

Meanwhile, in FIG. 1, after ink is coated on the printing blanket in step i), step ii) proceeds in a state that the solvent, particularly most of the high volatile solvents, are volatilized. Accordingly, the main components of the ink coating film, which is coated on the printing blanket when step ii) proceeds, are nano particles, a binder, and low volatile liquid components including a surfactant that remains in a small amount. Accordingly, in order to satisfy [Equation 2], it is preferred that one or more of the surface tension of the binder component and the surface tension of the low volatile liquid satisfy the critical surface tension of wetting or more of the surface of the printing blanket in [Equation 2].

In the present invention, Equations 1 and 2 are suitable for the reverse offset printing method even though there is no difference in the elements, but the effect of implementing a fine pattern is even better when there is a difference of 2 mN/m or more between the elements. For example, in Equation 1, the effect is even better when the difference between INK_{ST} and BNKγc is 2 mN/m or more. In Equation 2, the effect is even better when the difference between BNKγc and INK_{SE} is 2 mN/m or more. Furthermore, in Equation 2, the effect is even better when the difference between INK_{SE} and SUB_{SE} is 2 mN/m or more.

The conductive ink composition according to the present invention may be prepared by mixing the above-described components and filtering the components with a filter, if necessary.

The present invention provides a printing method using the ink composition. The printing method includes applying the ink composition on a printing blanket; removing a portion of a coating film on the printing blanket using a cliche; and transferring the coating film remaining on the printing blanket to an object to be printed. If necessary, subjecting the ink composition transferred to the object to be printed to heat treatment may be additionally included.

A finer pattern may be formed fairly well on the object to be printed by applying the reverse offset process using the ink composition. In particular, when the reverse offset process is applied using the ink composition, a fine pattern that may not be formed by an inkjet printing method and the like, which are applied in the related art, for example, a pattern having a line width and a line interval, which are 100 μm or less, preferably from about 1 μm to about 80 μm, and preferably from about 3 μm to about 40 μm, may be formed fairly well. In particular, it is possible to form even a pattern of fine line width/line interval having a line width of about 10 μm or less and a line interval of about 10 μm or less fairly well by using the ink composition and the reverse offset process.

Accordingly, fine pattern may be provided by applying the above-described ink composition and printing method according to the present invention. The pattern may be used as, for example, an electrode pattern of a flexible display device and a flat panel display device, and the like, thereby greatly contributing to the improvement in visibility and the large area of the flexible display device and the flat panel display device.

The heat treatment temperature of the ink composition according to the present invention may be selected in a range from 60° C. to 500° C., and the heat treatment time may be selected according to the component and composition of the composition, and the heat treatment may be performed, for example, for from 3 minutes to 60 minutes.

The present invention provides a printing method using the conductive ink composition. The method includes printing the conductive ink composition, and subjecting the conductive ink composition to heat treatment. The printing method is preferably a roll printing method, and more preferably a reverse offset printing method. The heat treatment temperature and time after printing are the same as those described above.

According to the present invention, it is possible to provide a pattern having a line width and a line interval, which are 100 μm or less, preferably from 3 μm to 80 μm, preferably from about 3 μm to about 40 μm, and more preferably from about 3 μm to about 10 μm. The pattern may be determined according to the final use thereof. The pattern may be a regular pattern such as a mesh pattern, or an irregular pattern.

Hereinafter, the present invention will be described in more detail with reference to Examples. However, the Examples are provided for illustrative purposes only, and the scope of the present invention is not limited thereto.

### EXAMPLE

25 g of a silver nano particle having an average particle diameter of 70 nm, 1 g of butylated hydroxyanisole, 33 g of ethanol, 3 g of butyl cellosolve, 36 g of isopropyl cellosolve and 0.6 g of a silicone-based surfactant were mixed, and the mixture was stirred for 24 hours and then filtered with a 1-micrometer filter to prepare an ink composition.

The ink composition was applied on a printing blanket made of silicone rubber, and then a cliche with a desired conductive pattern formed in an engraved shape was brought into contact with the blanket to remove ink on a non-pixel part with the cliche, thereby forming a pattern of the ink composition on the blanket. Thereafter, the printing blanket was brought into contact with a glass substrate to form a pattern on the glass substrate.

The initial surface tension of the ink was measured by a tensiometer, and was 22 mN/m.

The surface tension of butylated hydroxyanisole, which was a binder component of the ink, was 32.7 mN/m, and the surface tension of butyl cellosolve, which was a low volatile liquid, was 27 mN/m.

The surface energy of the printing blanket made of silicone rubber and the glass substrate and the surface energy of the ink coating film remaining on the surface of the blanket, after the ink composition was applied on the printing blanket and dried and immediately before the ink coating film was brought into contact with the cliche, were obtained by the above-described Fowkes method. That is, the surface tensions were calculated by measuring a water contact angle and a diiodomethane contact angle of each surface and then substituting the values of the angles into Equation 4.

At this time, the information on the surface tension of water and diiodomethane is as the following Table 1.

TABLE 1

| | γ_{L} (mN/m) | γ_{L}^{d} (mN/m) | γ_{L}^{p} (mN/m) |
|---|---|---|---|
| Water (H₂O) | 72.0 | 50.2 | 21.8 |
| Diiodomethane (CH₂I₂) | 50.4 | 50.4 | 0 |

At this time, the surface energy of the ink coating film remaining on the surface of the blanket immediately before the ink coating film was brought into contact with the cliche was calculated by substituting the values of the water contact angle and the diiodomethane contact angle of the ink coating film, which were measured 2 minutes after applying the ink composition on the printing blanket, into the equation.

The critical surface tension of wetting of the printing blanket was 24 mN/m (Jones R. G., Ando W and Chojnowsk J. 2000 Silicon-Containing Polymers (New York: Kluwer) p 214).

The water contact angle and diiodomethane contact angle of the glass base material were 27° and 34.7°, respectively, and when the surface energy of the glass base material was calculated therefrom by the Fowkes method, a value of 52.79 mN/m was obtained.

The water contact angle and diiodomethane contact angle of the ink coating film, which were measured 2 minutes after the ink composition was applied on the printing blanket, were 79° and 41°, respectively, and when the surface energy of the ink coating film was calculated therefrom by the Fowkes method, a value of 45.28 mN/m was obtained.

The pattern shape was observed with an optical microscope, and it could be confirmed that it was possible to form a fine pattern (FIG. 2).

### Comparative Example

30 g of a silver nano particle having an average particle diameter of 20 nm, 1.2 g of a phenolic polymeric binder, 33 g of ethanol, 2 g of butyl cellosolve, 36 g of isopropyl cellosolve and 0.6 g of a surfactant were mixed, and the mixture was stirred for 24 hours and then filtered with a 1-micrometer filter to prepare an ink composition.

Thereafter, a pattern was formed by performing printing in the same manner as in the Example, and was evaluated in the same manner as in the Example.

The initial surface tension of the ink was measured by a tensiometer, and was 22 mN/m.

The critical surface tension of wetting of the printing blanket was 24 mN/m.

The water contact angle and diiodomethane contact angle of the glass base material were 27° and 34.7°, respectively, and when the surface energy of the glass base material was calculated therefrom by the Fowkes method, a value of 52.79 mN/m was obtained.

The water contact angle and diiodomethane contact angle of the ink coating film, which were measured 2 minutes after the ink composition was applied on the printing blanket, were 72.3° and 29.3°, respectively, and when the surface energy of the ink coating film was calculated therefrom by the Fowkes method, a value of 53.4 mN/m was obtained.

The pattern shape after printing was observed, and as a result, the ink composition formed a hard film on the printing blanket 2 minutes after the ink composition was applied on the printing blanket, thereby generating cracks without being properly transferred to the glass base material. Even though the waiting time after the application was modified other than 2 minutes, the hard film was formed on the printing blanket in the same manner as described above.

What is claim is:

1. An ink composition, wherein the ink composition has properties such that, before printing, it satisfies INK_{ST}≤BNKγc [Equation 1], and
the ink composition has properties such that, when printed on a printing blanket, the ink composition satisfies BNKγc≤INK_{SE}≤SUB_{SE} [Equation 2], wherein in Equations 1 and 2,
INK_{ST} is an initial surface tension of the ink composition,
BNKγc is a critical surface tension of wetting of the printing blanket,
INK_{SE} is a surface energy of the ink coating film on the printing blanket, and
SUB_{SE} is a surface energy of an object to be printed, and said ink composition having properties such that conditions a)-c) are satisfied by said ink composition:
a) INK_{ST} is 2 mN/m or more different from BNKγc in Equation 1;
b) INK_{SE} is 2 mN/m or more different from BNKγc in Equation 1; and
c) INK_{SE} is 2 mN/m or more different from SUB_{SE} in Equation 2,
the ink composition having said properties comprising: silver particles having a diameter of 5 nm and 800 nm in an amount of from 10 wt % to 50 wt % based on the total weight of the ink composition; at least two different solvents, a binder, and a silicone-based or a fluorine-based surfactant,
wherein said silver particles, solvents, binder, and silicone-based or a fluorine-based surfactant are present in said ink composition in relative amounts effective to impart said properties satisfying Equation 1, Equation 2, and conditions a)-c).

2. The ink composition of claim 1, wherein said and silicone-based or a fluorine-based surfactant is present in an amount of from 0.01 wt % to 5 wt % based on the total weight of the ink composition.

3. The ink composition of claim 1, wherein the binder has a surface tension from 26 mN/m to 45 mN/m.

4. The ink composition of claim 1, wherein said at least two different solvents comprise a first solvent in an amount of 10 wt % to 40 wt % based on the total weight of the ink composition and a second solvent in an amount of 0.1 wt % to 50 wt % based on the total weight of the ink composition.

5. The ink composition of claim 4, wherein the first solvent comprises a solvent having a surface tension from 11 mN/m to 24 mN/m and the second solvent comprises a solvent having a surface tension from 26 mN/m to 72 mN/m.

6. The ink composition of claim 4, wherein said first solvent is selected from the group consisting of dimethyl glycol, trimethyl chloro methane, methanol, ethanol, isopropanol, propanol, hexane, heptane, octane, 1-chlorobutane, methyl ethyl ketone, cyclohexane.

7. The ink composition of claim 4, wherein said second solvent is selected from the group consisting of dimethyl acetamide, γ-butyl lactone, hydroxytoluene, propylene glycol monobutyl ether, propylene glycol monopropyl ether, butyl cellosolve, glycerin, butyl carbitol, methoxy propoxy propanol, carbitol, terpinol, triethylene glycol monoethyl ether, triethylene glycol monomethyl ether, N-methylpyrrolidone, propylene carbonate, dimethyl sulfoxide, diethylene glycol, triethanolamine, diethanolamine, triethylene glycol, ethylene glycol.

8. The ink composition of claim 1, further comprising a conductive particle selected from the group consisting of a copper particle, a palladium particle, a gold particle, a nickel particle, a conductive polymer particle, and a mixture thereof.

9. The ink composition of claim 1, wherein the binder is selected from the group consisting of a novolac resin, a butyl acrylic resin, a butyl methacrylic resin, a benzyl methacrylic resin, an ethyl methacrylic resin, a methyl methacrylate-based resin, polyvinylpyrrolidone, ethyl cellulose, hydroxypropylmethyl cellulose, a styrene resin, a polyvinyl acetate-based resin, and a copolymer of at least two thereof.

10. A kit comprising an ink composition, a printing blanket and an object to be printed, wherein the ink composition has properties such that, before printing, it satisfies INK_{ST}≤BNKγc [Equation 1], and
the ink composition has properties such that, when printed on the printing blanket, the ink composition satisfies BNKγc≤INK_{SE}≤SUB_{SE} [Equation 2], wherein in Equations 1 and 2,
INK_{ST} is an initial surface tension of the ink composition,
BNKγc is a critical surface tension of wetting of the printing blanket,
INK_{SE} is a surface energy of the ink coating film on the printing blanket, and
SUB_{SE} is a surface energy of the object to be printed, and said ink composition having properties such that conditions a)-c) are satisfied by said ink composition:
d) INK_{ST} is 2 mN/m or more different from BNKγc in Equation 1;
e) INK_{SE} is 2 mN/m or more different from BNKγc in Equation 1; and
f) INK_{SE} is 2 mN/m or more different from SUB_{SE} in Equation 2,
the ink composition having said properties comprising: silver particles having a diameter of 5 nm and 800 nm in an amount of from 10 wt % to 50 wt % based on the total weight of the ink composition; at least two different solvents, a binder, and a silicone-based or a fluorine-based surfactant,
wherein said silver particles, solvents, binder, and silicone-based or a fluorine-based surfactant are present in said ink composition in relative amounts effective to impart said properties satisfying Equation 1, Equation 2, and conditions a)-c).

11. The kit of claim 10, wherein said and silicone-based or a fluorine-based surfactant is present in an amount of from 0.01 wt % to 5 wt % based on the total weight of the ink composition.

12. The kit of claim 10, wherein the binder has a surface tension from 26 mN/m to 45 mN/m.

13. The kit of claim 10, wherein said at least two different solvents comprise a first solvent in an amount of 10 wt % to 40 wt % based on the total weight of the ink composition and a second solvent in an amount of 0.1 wt % to 50 wt % based on the total weight of the ink composition.

14. The kit of claim 13, wherein the first solvent comprises a solvent having a surface tension from 11 mN/m to 24 mN/m and the second solvent comprises a solvent having a surface tension from 26 mN/m to 72 mN/m.

15. The kit of claim 13, wherein said first solvent is selected from the group consisting of dimethyl glycol, trimethyl chloro methane, methanol, ethanol, isopropanol, propanol, hexane, heptane, octane, 1-chlorobutane, methyl ethyl ketone, cyclohexane.

16. The kit of claim 13, wherein said second solvent is selected from the group consisting of dimethyl acetamide, γ-butyl lactone, hydroxytoluene, propylene glycol monobutyl ether, propylene glycol monopropyl ether, butyl cellosolve, glycerin, butyl carbitol, methoxy propoxy propanol, carbitol, terpinol, triethylene glycol monoethyl ether, triethylene glycol monomethyl ether, N-methylpyrrolidone, propylene carbonate, dimethyl sulfoxide, diethylene glycol, triethanolamine, diethanolamine, triethylene glycol, ethylene glycol.

17. The kit of claim 10, further comprising a conductive particle selected from the group consisting of a copper particle, a palladium particle, a gold particle, a nickel particle, a conductive polymer particle, and a mixture thereof.

18. The kit of claim 10, wherein the binder is selected from the group consisting of a novolac resin, a butyl acrylic resin, a butyl methacrylic resin, a benzyl methacrylic resin, an ethyl methacrylic resin, a methyl methacrylate-based resin, polyvinylpyrrolidone, ethyl cellulose, hydroxypropylmethyl cellulose, a styrene resin, a polyvinyl acetate-based resin, and a copolymer of at least two thereof.
